(19) United States
(12) Patent Application Publication
(10) Pub. No.: US 2024/0068083 A1
(43) Pub. Date: Feb. 29, 2024

(54) ALTIN-CRN-BASED COATING FOR FORMING TOOLS

(71) Applicant: Oerlikon Surface Solutions AG, Pfaffikon, Pfaffikon (CH)

(72) Inventors: Anders Olof ERIKSSON, Chur (CH); Ali KHATIBI, Chur (CH)

(21) Appl. No.: 18/258,055

(22) PCT Filed: Dec. 17, 2021
(86) PCT No.: PCT/EP2021/086621

§ 371 Date: Jun. 16, 2023

(30) Foreign Application Priority Data
Dec. 17, 2020 (DE) 102020133901.1

(51) Int. Cl. C23C 14/06; C23C 14/02; C23C 14/54

(52) U.S. Cl. CPC C23C 14/0617; C23C 14/024; C23C 14/548

(57) ABSTRACT

The present invention relates to a coating for forming tools to be used in a forming operation of a workpiece material, wherein the coating is deposited on a substrate surface and the coating comprises a lower layer (10) and an upper layer (20), wherein the lower layer (10) is deposited closer to the substrate surface than the upper layer (20), wherein the lower layer (10) mainly comprises chromium nitride, and the upper layer (20) is deposited as multilayer formed by a plurality of A-layers (22) and B-layers (21) deposited alternate one on each other forming a sequence of . . . /A/B/A/B/A/B/ . . . -layers (22,21), wherein the A-layers (22) mainly comprise aluminum titanium nitride, and the B-layers (21) mainly comprise chromium nitride.

The present invention relates to a AlTiN/CrN-based coating for improving performance of forming tools (e.g. dies and punches), in particular but not exclusively for improving performance of forming tools to be used for cold forming of high-strength metal sheets, or for aluminum forming operations such as aluminum die casting or hot forming of aluminum sheets. The invention is also suitable for other kinds of forming operations, e.g. high pressure die casting, etc.

### TECHNICAL FIELD

Coatings are commonly applied on surfaces of different kind of tools. Very known is the use of coating applied on cutting surfaces of cutting tools, for example for improving cutting tool performance.

In the last years also the use of coatings for improvement of performance of forming tools has increased.

However, the requirements to be met by coatings used for improving performance of cutting tools usually differ from the requirements to be met by coatings used for improving performing of forming tools.

Dies and punches are forming tools that are commonly used for accomplishing forming operations such as cold forming of high-strength steels.

Current trends in different industries, e.g. in the automotive industry involve increased use of high strength steels for making possible light-weight designs. In manufacturing processes comprising forming operations of such high strength steels as workpiece materials, the lifetime of the forming tool is found to be limited by abrasive and adhesive wear. In particular forming operations of workpiece materials of the type Carbon Steels (also called Advanced High Strength Steels—acronym: AHSS) constituted a big challenge because of their very high tensile strengths ranging from ˜550 MPa extending to above 1000 MPa. The strong abrasive and adhesive wear that occurs in such cases leads to frequent change of forming tools which involves frequent production interruptions and results in a considerable loss of productivity.

Until now some different surface treatments and/or coating solutions to be applied to surfaces of the workpiece material surfaces be formed or to the forming tools or coating members to be used for accomplishing the forming operation of the workpiece materials have been suggested for solving the above-mentioned problem.

Young (U.S. Pat. No. 7,587,919 B1) suggests the use of wear resistant coating layers from the group of CrN, AlCrN, TiCrN, TiN, TiCN, and TiAlN in a thickness from about 3 microns to about 8 microns, or multilayers of alternating TiN—TiCN—TiN in a thickness from about 5 microns to about 10 microns. These layers are preferably applied by Physical Vapor Deposition (PVD). Furthermore, nitriding as surface preparatory step is found beneficial to ensure proper adhesion of the coating to the surface.

Cha (U.S. Pat. No. 8,746,027 B2) describes multilayer mold coating comprising: a junction layer of CrN or Ti(C)N in a thickness of about 0.5 μm to about 5 μm; a first TiAlN/CrN nano multilayer comprising TiAlN and CrN nano layers alternately coated in thickness of about 10-50 nm to a total thickness of 0.5-5 μm for the first nano multilayer; a second TiAlCN/CrCN nano-multilayer comprising 1-30 at % C in a total thickness of the second nano-multilayer of 0.5-5 μm. In the first TiAlN/CrN nano-multilayer, the ratio of Ti:Al:Cr may be 1:1:1.

Furthermore, state of the art describes several embodiments of C-containing layers obtained through supplying hydrocarbon process gases. Due to the reactivity of such hydrocarbon (CxHy) process gases, contamination of the interior part of the PVD coating apparatus may be problematic, in particular if deposition processes involving hydrocarbon gases are alternated with processes requiring low C-contamination using the same PVD coating chamber. Additional cleaning steps might in such situations be necessary. It is therefore an objective of the present innovation to provide a coating solution with excellent performance in forming of AHSS, without the application of hydrocarbon gases.

### OBJECTIVE OF THE PRESENT INVENTION

The main objective of the present invention is providing a coating and a forming tool with improved performance as well as a method for producing the coatings.

Preferably, the coating according to the present invention allows attaining increased tool life of forming tools used for cold forming of any of the above-mentioned high-strength steels, in particular by cold forming of AHSS.

### DESCRIPTION OF THE PRESENT INVENTION

The objective of the present invention is attained by providing a new coating as described below and as claimed in claim 1, a forming tool as described below and as claimed in claim 8, as well as a method for producing the new coating as described below and claimed in claim 9. Further claims 2 to 7 and claims 10 to 12 describe preferred embodiments of the present invention.

Further features and details of the invention result from the dependent claims, the description and the drawings. Features and details which have been described in connection with the coating and/or the forming tool according to the invention naturally also apply in connection with the method according to the invention and vice versa in each case, so that with regard to the disclosure concerning the individual aspects of the invention reference is or can always be made mutually.

A coating according to the present invention is especially suitable for forming tools to be used in a forming operation of a workpiece material. The inventive coating is deposited on a substrate surface and the coating comprises a lower layer and an upper layer, wherein the lower layer is deposited closer to the substrate surface than the upper layer, wherein the lower layer consists of chromium nitride or mainly comprises chromium nitride, preferably consists of chromium nitride, and the upper layer is deposited as multilayer formed by a plurality of A-layers and B-layers deposited alternate one on each other forming a sequence of . . . /A/B/A/B/A/B/ . . . -layers, wherein the A-layers consist of aluminum titanium nitride or mainly comprises aluminum titanium nitride, preferably consists of aluminum titanium nitride, and the B-layers consist of chromium nitride or mainly comprise chromium nitride, preferably consist of chromium nitride, wherein:
the upper layer thickness tlᵤₚₚₑᵣ is higher than the lower layer thickness tl_{lower}, wherein:
   tlᵤₚₚₑᵣ+tl_{lower}≥5 μm, and
   tlᵤₚₚₑᵣ/tl_{lower}≥1.2,
in the upper layer the content of aluminum Al_{content[at %]} is higher than the content of titanium Ti_{content[at %]} in atomic ratio, if only aluminum and titanium are considered, wherein Al_{content[at %]}/Ti_{content[at %]}≥1.5, and
the upper layer comprises cubic phase, in particular face-centered cubic phase.

New coatings according to the present invention can be used to provide especially high wear resistance, regarding both abrasive and adhesive wear, as well as good fatigue resistance to forming tools.

The term “mainly comprises” means that the majority of a layer consists of the named substance. In particular, “mainly comprises” can encompass comprising to a proportion of over 80% or preferably over 90%.

In particular, the lower layer can be deposited directly on the substrate, thereby forming a bottom layer or base layer. The upper layer can also be regarded as a second coating layer, wherein the lower layer is the first coating layer.

Preferably, it can be provided that the NB-bilayer period formed by the sum of the thickness of one A-layer and the thickness of one B-layer deposited one on each other is in a nanometer range, preferably tl_{oneA-layer}+tl_{oneB-layer}≤100 nm, more preferably 10 nm≤tl_{oneA-layer}+tl_{oneB-layer}≤70 nm.

Also, it can be provided that the bilayer period is in the range 30 nm≤tl_{oneA-layer}+tl_{oneB-layer}≤60 nm.

Furthermore, it may be provided that the ratio of the thickness of a B-layer in comparison to an A-layer deposited close to the B-layer is 0.8≤tl_{oneB-layer}/tl_{oneA-layer}<2, preferably 1≤tl_{oneB-layer}/tl_{oneA-layer}≤1.9, more preferably 1≤tl_{oneB-layer}/tl_{oneA-layer}≤1.3.

Furthermore, it may be provided that the hardness of the upper layer Hᵤₚₚₑᵣ measured by nanoindentation is in a range Hᵤₚₚₑᵣ≥20 GPa, preferably 30≥Hᵤₚₚₑᵣ≥20 GPa.

Preferably, it can be provided that the reduced Youngs Modulus Er or the elastic modulus E of the upper layer Erᵤₚₚₑᵣ or Eᵤₚₚₑᵣ measured by nanoindentation is in a range 400≥Erᵤₚₚₑᵣ≥300 GPa or 400≥Eᵤₚₚₑᵣ≥300 GPa.

Also, it can be provided that the upper layer forms the outer surface of the coating, wherein in particular the A-layer or the B-layer forms the outer surface of the coating. In other words, no further layer is arranged on top of the upper layer, so that the upper layer is in contact with the environment. The upper layer according to the invention provides superior surface properties as mentioned above, and avoiding the deposition of further layers on top of the upper layer preserves these properties and reduces the time and cost required to deposit the coating.

In another aspect of the invention, a forming tool, in particular a die or a punch, for cold forming of high-strength metal sheets, with a coating according to the invention is provided.

Thus, a forming tool according to the invention brings the same advantages as have been described in detail with reference to a coating according to the invention.

In another aspect of the invention, a method for producing a coating according to the invention is provided, wherein the at least one lower level and upper level is deposited by means of physical vapor deposition techniques onto substrate surfaces of a forming tool, with at least one target comprising chromium and at least one target comprising titanium and aluminum.

Thus, a method according to the invention brings the same advantages as have been described in detail with reference to a coating according to the invention.

In particular, it can be provided that the sequence of alternating . . . A/B/NB/NB . . . layers is created by alternating exposure of the substrate to the at least one target comprising chromium and the at least one target comprising titanium and aluminum.

Furthermore, it may be provided that the alternating exposure is created by translational motion, in particular rotation along at least one vertical axis, of the substrate.

Also, it can be provided that a nitriding pre-treatment step is performed at least before depositing the lower layer, the upper layer or in between depositing the A-layer or the B-layer. This provides the advantage of a substantially higher hardness on the surface of the substrate or the deposited layers. In particular, the nitriding pre-treatment step can be carried out as a plasma nitriding pre-treatment step, which results in a lower ecological impact of the process in comparison to a wet chemical process.

Further measures improving the invention result from the following description of some embodiments of the invention, which are shown schematically in the figures. All features and/or advantages arising from the claims, the description or the drawings, including constructional details, spatial arrangements and process steps, may be essential to the invention both individually and in a wide variety of combinations. It should be noted that the figures are descriptive only and are not intended to limit the invention in any way.

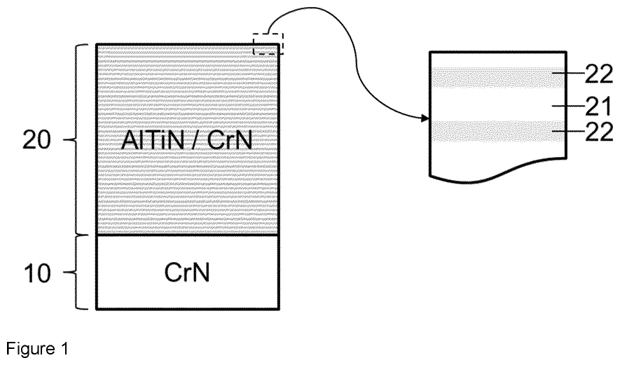

FIG. 1: Schematic overview of the inventive coating structure, consisting of a CrN bottom layer 10 followed by a sequence of multilayers 20 comprising a plurality of CrN layers 21 and TiAlN layers 22, in particular consisting of a plurality of CrN layers (21) and TiAlN layers (22).

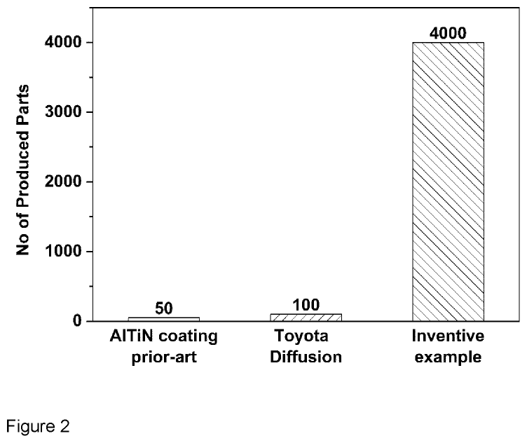

FIG. 2: Application example of the inventive coating showing performance in drawing of AHSS. The inventive coating allowed a multifold increased tool life, i.e. increase in number of produced parts, compared to tools coated with prior-art AlTiN coatings and tools prepared with Toyota Diffusion process.

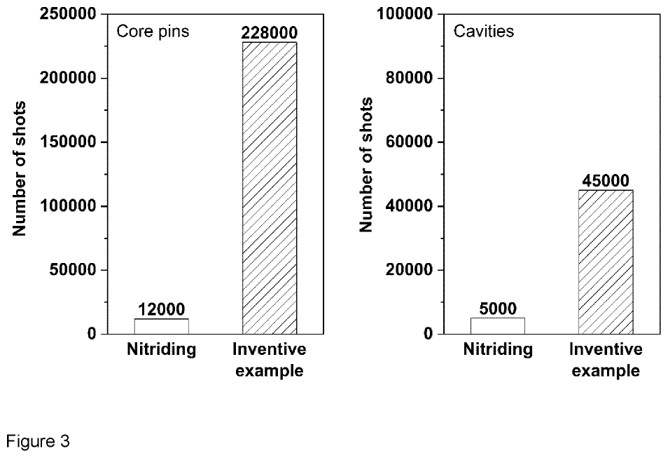

FIG. 3: Application example of the inventive coating showing performance in high pressure die casting of an aluminum alloy with 9% silicon. The inventive coating allowed a multifold increased in the useful life, i.e. number of shots, of core pins and cavities compared to core pins and cavities prepared by nitriding.

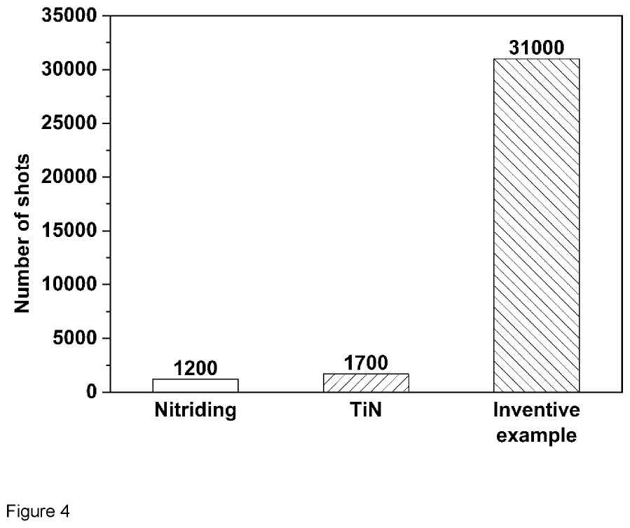

FIG. 4: Application example of the inventive coating showing performance in high pressure die casting of an aluminum alloy with 17% silicon. The inventive coating allowed a multifold increased in the useful life, i.e. number of shots, of core pins compared to core pins that were only nitride or nitride and coated with TiN.

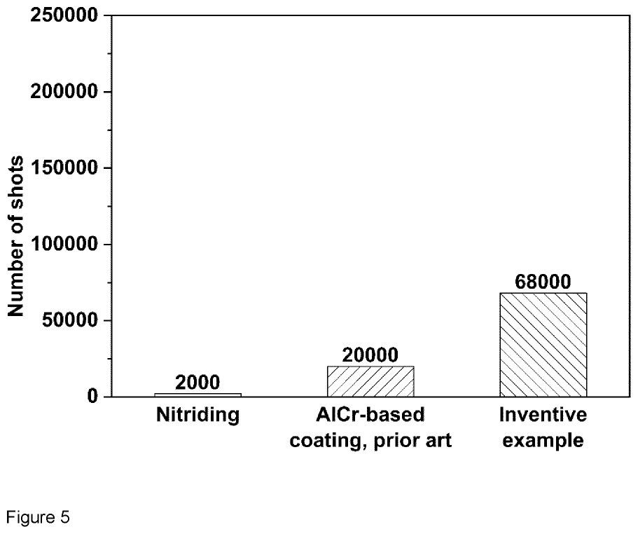

FIG. 5: Application example of the inventive coating showing performance in high pressure die casting of magnesium liquid at 680° C. The inventive coating allowed a multifold increase in the useful life, i.e. number of shots, of core pins compared to core pins that were only nitride or coated with an AlCrN-coating according to prior-art.

The objective of the innovation is obtained by providing multilayer coating comprising a CrN base layer 10 followed by at least one second coating layer 20, comprising a plurality of AlTiN 22 & CrN 21 nanolayers or in particular consisting of a plurality of AlTiN 22 & CrN 21. The coating design was tuned including: the chemical composition of the individual layers, in particular the AlTiN nanolayers; the crystalline phase structure, the mechanical properties, the periodicity of the AlTiN & CrN nanolayers, and the ratio between the coating layers. Surprisingly, a coating with excellent performance in cold forming of AHSS was achieved.

For the AlTiN-nanolayers 22, it was found advantageous to use an Al-content that in atomic percentage (at. %) is higher than the content of Ti in atomic percentage. Preferred is a ratio in atomic percent of Al to Ti of at least Al:Ti=60:40 in at %, further preferred about Al:Ti=65:35 in at %.

Preferably the phase structure of the TiAlN nanolayers 22 should contain cubic phases, further preferable is that the TiAlN nanolayers 22 predominantly contains cubic phases.

The second coating layer 20 should preferably have an indentation hardness (HIT), as measured with nanoindentation, exceeding 20 GPa. More preferable, about 25-30 GPa. The elastic modulus, E-Modulus, or also called Young's modulus, measured with nanoindentation should be about 300-400 GPa, more preferable 320-360 GPa.

The CrN base layer should preferably have a thickness ratio of 1:4 versus the second coating layer. In other words, the ratio calculated as [Thickness of layer 20]/[Thickness of layer 10] should be about 4. The total thickness of the base layer 10 and the second coating layer 20 should preferably be larger than 5 μm, more preferably in the range of 5-15 μm.

The bilayer period in the second coating layer, i.e. the sum of thicknesses for one AlTiN layer 22 and one CrN layer 21, was found to be preferably in the range 10-70 nm, more preferably 30-50 nm.

It is furthermore preferable that the thickness of the CrN nanolayers 21 is equal or higher than the AlTiN nanolayers 22. In other words, the layer thickness ratio of CrN 21 to AlTiN 22 is ≥1. In particular if the ratio is about 1.3.

Further Improvements

Application of the described coatings can be combined with nitriding pre-treatment. This can be done either in a separate vacuum or atmospheric nitriding process, or in-situ prior to application of the first surface layer.

### One Detailed Example

A coating according to the present innovation was deposited using an Oerlikon Balzers INNOVA PVD deposition system. A base layer of CrN was deposited through arc deposition from 4 Cr-targets operated at 150 A arc current in an N₂-atmosphere. A second coating layer was formed through co-arcing of two Cr-targets and two AlTi-targets with a composition of Al:Ti 67:33 in at. %, in N₂-atmosphere. The Cr-targets and the AlTi-targets were positioned on different sides of the coating system, and the nanolayers of CrN and AlTiN were formed through substrate rotation causing alternating exposure of the deposition fluxes from the Cr-targets and the AlTi-targets. The substrate rotation speed was adjusted such that the bilayer period of the CrN/AlTiN multilayer coatings were about 50 nm. The deposition time was adjusted so that the total coating thickness where about 12 um, whereof the base layer of CrN constituted 20%, i.e. ca 2.4 um.

Prior to deposition of the coating, an in-situ ion etch was performed.

Automotive SKD11 material were coated with the inventive coating. Prior to the coating process, the steel dies were nitride and polished to a roughness of about Ra 0.11 um. After the coating process, the tools were post-polished to a roughness of about Ra 0.12 um.

The dies were tested in a 20 mm drawing application of 1.2 mm thick AHSS with tensile strength of 1200 MPa. The tool lifetime could be increased by a factor of 80, compared to a prior-art TiAlN coating, as well as a factor of 40 compared to state-of-the-art Toyota Diffusion process. See FIG. 2.

High Pressure Die Casting (HPDC)-Application Examples:

The inventors also found the invention to be particularly useful for high pressure die casting applications. FIG. 3 shows the useful life of core pins (left) and cavities (right) used in a high pressure die casting setup of an aluminum alloy with 9% silicon. The core pins that were nitride and coated with the inventive coating allowed a more than 15-fold increase in the lifetime compared to nitriding treatment only. On cavities, nitriding followed by the inventive coating allowed a 9-fold increase in lifetime, without any cleaning or maintenance, compared to cavities with nitriding treatment only.

FIG. 4 shows a further example of high pressure die casting where an aluminum alloy with 17% silicon was used. Core pins that were nitride and coated with the inventive coating allowed multifold increases of lifetime compared with core pins that were nitrided only or coated with TiN.

An application example with high pressure die casting of magnesium liquid at 680° C. is shown in FIG. 5. This application is challenging since magnesium, being lighter than aluminum, enters the mold at higher speed and creates more abrasive wear. The lifetime of core pins could be multiplied by applying a nitriding treatment and the inventive coating, compared to core pins that were nitride only or coated with a prior-art AlCr-based coating. The inventive coating also showed advantages in terms of better part quality, less sticking of melt to the pin, and less machine down-time.

The foregoing explanation of the embodiments describes the present invention exclusively in the context of examples. Of course, individual features of the embodiments can be freely combined with each other, provided that this is technically reasonable, without leaving the scope of the present invention.

### REFERENCE SKINS

10 lower layer, bottom layer, CrN base layer
20 upper layer, second coating layer
21 B-layer, CrN layer
22 A-layer, TiAlN layer

1. A coating for forming tools to be used in a forming operation of a workpiece material, wherein the coating is deposited on a substrate surface and the coating comprises a lower layer and an upper layer, wherein the lower layer is deposited closer to the substrate surface than the upper layer, wherein the lower layer mainly comprises chromium nitride and the upper layer is deposited as multilayer formed by a plurality of A-layers and B-layers deposited alternate one on each other forming a sequence of . . . /A/B/A/B/A/B/ . . . -layers, wherein the A-layers mainly comprise aluminum titanium nitride and the B-layers mainly comprise chromium nitride, wherein the coating:
the upper layer thickness tlᵤₚₚₑᵣ is higher than the lower layer thickness tl_{lower}, wherein:
tlᵤₚₚₑᵣ+tl_{lower}≥5 μm, and
tlᵤₚₚₑᵣ/tl_{lower}≥1.2,
in the upper layer the content of aluminum Al_{content[at %]} is higher than the content of titanium Ti_{content[at %]} in atomic ratio, if only aluminum and titanium are considered, wherein Al_{content[at %]}/Ti_{content[at %]}≥1.5, and
the upper layer comprises cubic phase.

2. The coating according to claim 1, wherein the A/B-bilayer period formed by the sum of the thickness of one A-layer and the thickness of one B-layer deposited one on each other is in a nanometer range.

3. The coating according to claim 2, in wherein the bilayer period is in the range 30 nm≤tl_{oneA-layer}+tl_{oneB-layer}≤60 nm.

4. The coating according to claim 1, wherein a ratio of the thickness of a B-layer in comparison to an A-layer deposited close to the B-layer is 0.8≤tl_{oneB-layer}/tl_{oneA-layer}<2.

5. The coating according to claim 1, wherein a hardness of the upper layer Hᵤₚₚₑᵣ measured by nanoindentation is in a range Hᵤₚₚₑᵣ≥20 GPa.

6. The coating according to claim 1, wherein a reduced Youngs Modulus Er or the elastic modulus E of the upper layer Erᵤₚₚₑᵣ or Eᵤₚₚₑᵣ measured by nanoindentation is in a range 400≥Erᵤₚₚₑᵣ≥300 GPa or 400≥Eᵤₚₚₑᵣ≥300 GPa.

7. The coating according to claim 1, wherein the upper layer forms an outer surface of the coating.

8. A forming tool for cold forming of high-strength metal sheets, with a coating according to claim 1.

9. A method for producing a coating according to claim 1, wherein the at least one lower layer and upper layer is deposited by means of physical vapor deposition techniques onto substrate surfaces of a forming tool, with at least one target comprising chromium and at least one target comprising titanium and aluminum.

10. The method according to claim 9, wherein the sequence of alternating . . . A/B/A/B/A/B . . . layers is created by alternating exposure of the substrate to the at least one target comprising chromium and the at least one target comprising titanium and aluminum.

11. The method according to claim 10, where the alternating exposure is created by translational motion of the substrate.

12. The method according to claim 9, wherein a nitriding pre-treatment stage is performed at least before depositing the lower layer, the upper layer or in between depositing the A-layer or the B-layer.

13. The coating according to claim 1, wherein, the upper layer thickness tlᵤₚₚₑᵣ is higher than the lower layer thickness tl_{lower}, wherein:
tlᵤₚₚₑᵣ+tl_{lower}≥5 μm, and
3≤tlᵤₚₚₑᵣ/tl_{lower}≤6.

14. The coating according to claim 1, wherein, the upper layer thickness tlᵤₚₚₑᵣ is higher than the lower layer thickness tl_{lower}, wherein:
tlᵤₚₚₑᵣ+tl_{lower}≥5 μm, and
tlᵤₚₚₑᵣ/tl_{lower}=4.

15. The coating according to claim 1, wherein the upper layer comprises face-centered cubic phase.

16. The coating according to claim 2, wherein the nanometer range is 10 nm≤tl_{oneA-layer}+tl_{oneB-layer}≤70 nm.

17. The coating according to claim 4, wherein the ratio is 1≤tl_{oneB-layer}/tl_{oneA-layer}≤1.3.

18. The coating according to claim 5, wherein the hardness of the upper layer is in a range 30≥Hᵤₚₚₑᵣ≥20 GPa.

19. The coating according to claim 7, wherein the A-layer or the B-layer forms the outer surface of the coating.

20. The method according to claim 11, where the alternating exposure is created by a rotation along at least one vertical axis.
